(19) United States
(12) Patent Application Publication
(10) Pub. No.: US 2023/0096911 A1
(43) Pub. Date: Mar. 30, 2023

(54) SEMICONDUCTOR DEVICE AND METHOD FOR FABRICATING THE SAME

(71) Applicant: SK hynix Inc., Icheon-si (KR)

(72) Inventor: Mir IM, Icheon-si (KR)

(21) Appl. No.: 17/696,757

(22) Filed: Mar. 16, 2022

(30) Foreign Application Priority Data
Sep. 28, 2021 (KR) 10-2021-0127975

(51) Int. Cl. H01L 49/02; H01L 27/108

(52) U.S. Cl. CPC H01L 28/56; H01L 27/10805; H01L 28/91; H01L 28/92

(57) ABSTRACT

A capacitor includes: a bottom electrode; a top electrode; and a hybrid dielectric layer including at least one nanosheet material disposed between the bottom electrode and the top electrode.

### CROSS-REFERENCE TO RELATED APPLICATIONS

The present application claims priority under 35 U.S.C. § 119(a) to Korean Patent Application No. 10-2021-0127975, filed on Sep. 28, 2021 in the Korean Intellectual Property Office, which is incorporated herein by reference in its entirety.

### BACKGROUND

### 1. Field

Exemplary embodiments of the present disclosure relate to a semiconductor device, and more particularly, to a semiconductor device including a capacitor and a method for fabricating the semiconductor device.

### 2. Description of the Related Art

Recently, as design rules continue to decrease, semiconductor devices have been developed with greater capacity and a higher degree of integration. These trends are also seen in Dynamic random-access memory (DRAM) devices. In order for a DRAM device to operate, memory cells must have capacitance of a minimum predetermined level or higher.

### SUMMARY

Embodiments of the present invention are directed to a semiconductor device including a capacitor, and a method for fabricating the semiconductor device.

In accordance with an embodiment of the present disclosure, a capacitor includes: a bottom electrode; a top electrode; and a hybrid dielectric layer including at least one nanosheet material disposed between the bottom electrode and the top electrode.

In accordance with another embodiment of the present disclosure, a semiconductor device includes: a transistor including a first source/drain region, a second source/drain region, and a channel between the first source/drain region and a second source/drain region; a word line positioned over the channel of the transistor; a bit line coupled to the first source/drain region of the transistor; and a capacitor coupled to the second source/drain region of the transistor, wherein the capacitor includes: a bottom electrode coupled to the second source/drain region; a top electrode; and a hybrid dielectric layer including at least one nanosheet material disposed between the bottom electrode and the top electrode.

### BRIEF DESCRIPTION OF THE DRAWINGS

FIG. 1A is a cross-sectional view illustrating a capacitor in accordance with an embodiment of the present disclosure.

FIGS. 1B to 1D are cross-sectional views illustrating capacitors in accordance with other embodiments of the present disclosure.

FIG. 2 illustrates a semiconductor device in accordance with an embodiment of the present disclosure.

FIGS. 3A to 3G illustrate an example of a method for fabricating a semiconductor device in accordance with an embodiment of the present disclosure.

FIGS. 4 to 6 illustrate semiconductor devices in accordance with other embodiments of the present disclosure.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where one or more other exists between the first layer and the second layer or the substrate.

A paraelectric material may include HfO₂, ZrO₂, TiO₂, or a combination thereof. However, the paraelectric material has limitations in reducing the effective oxide thickness (Tox) due to its low dielectric constant (k<60) of less than approximately 60.

A material having a higher dielectric constant than the paraelectric material, that is, a super high-k material, has been proposed for use in memory devices. The super high-k material may include a bulk perovskite material, as an example. The bulk perovskite material may include BaTiO₃, PZT, or the like. However, in applications, the bulk perovskite material can present problems because the dielectric constant decreases rapidly at thin thicknesses.

A capacitor of a highly integrated DRAM may require a super high-k material having an effective oxide thickness (Tox) of approximately two angstroms (2 Å) or less and a dielectric constant of approximately 60 or more at a thickness of approximately five nanometers (5 nm) or less.

A negative capacitor has been proposed for capacitance boosting. A hybrid dielectric layer of a negative capacitor may include a stack of a ferroelectric material and a paraelectric material. However, the capacitance may drop sharply due to inter-mixing of atoms between the electrodes in the memory device and the hybrid dielectric layer. For example, the negative capacitance may drop sharply due to inter-mixing of atoms between the electrodes and a ferroelectric material, between the electrodes and a paraelectric material, and between the paraelectric material and the ferroelectric material.

The embodiments described below relate to a negative capacitor that may include a hybrid dielectric layer having a negative capacitance.

The hybrid dielectric layer may include a stack with a nanosheet material and a ferroelectric material. The nanosheet material may be a two-dimensional oxide nanosheet, and may have a thickness of approximately 0.4 to 2 nanometers (nm). The nanosheet material may have a super high-k material of approximately 200 or greater. The nanosheet material may be selected so that the dielectric constant of the nanosheet does not decrease with a decrease in sheet thickness. The nanosheet material may have a clean interface.

The nanosheet material may include a super high-k material including titanium (Ti), niobium (Nb), calcium (Ca), strontium (Sr), tantalum (Ta), europium (Eu), lanthanum (La), and combinations thereof. For example, the nanosheet material may include Ti_{0.87}O₂, Ti_{0.91}O₂, Nb₃O₈, TiNbO₅, Ti₂NbO₇, Ti₅NbO₁₄, Ca₂Nb₃O₁₀, Ca₃Nb₄O₁₃, Ca₄Nb₅O₁₆, Sr₂Nb₃O₁₀, Sr₃Nb₄O₁₃, Sr₄Nb₅O₁₆, Ca₂Ta₃O₁₀, Ca₃Ta₄O₁₃, Ca₄Ta₅O₁₆, Sr₂Ta₃O₁₀, Sr₃Ta₄O₁₃, Sr₄Ta₅O₁₆, Eu_{0.53}Ta₂O₇, or LaNb₂O₇. The nanosheet material may be crystalline.

The ferroelectric material may include a perovskite-based material. For example, the ferroelectric material FE may include Hf₁₋ₓZrₓO₂ (0<x<1), doped Hf₁₋ₓZrₓO₂ (dopant: La, Si, Y, Al), Ba₁₋ₓSrₓTiO₃ (0<x<1), PbTiO₃, PbZr₁₋ₓTiₓO₃ (0<x<1), BiFeO₃, or a combination thereof.

A method for forming a nanosheet material may include coating a polymer material having a positive charge, depositing an inorganic nanosheet having a negative charge, and removing the polymer material by performing an super violet ray (UV) treatment. The polymer material may include PDDA or PEI. Deposition of the inorganic nanosheet may include a layer-by-layer deposition (LBL) deposition method.

The ferroelectric material may be deposited by Atomic Layer Deposition (ALD).

A dielectric layer including the nanosheet material may prevent intermixing between the ferroelectric material and the nanosheet material.

The dielectric layer including the nanosheet material may prevent the formation of an amorphous layer having a low dielectric constant between the top and bottom electrodes and the dielectric layer in a subsequent high-temperature heat treatment and may prevent deterioration of the negative capacitance.

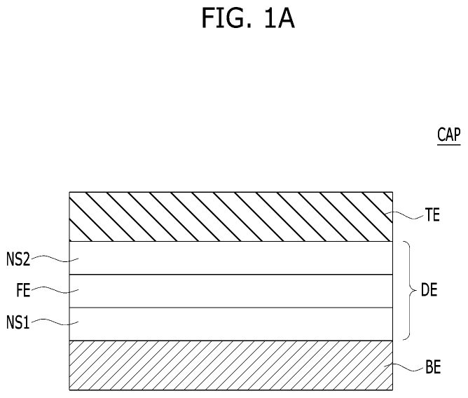

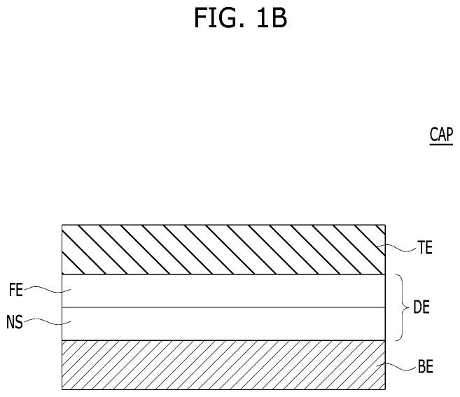

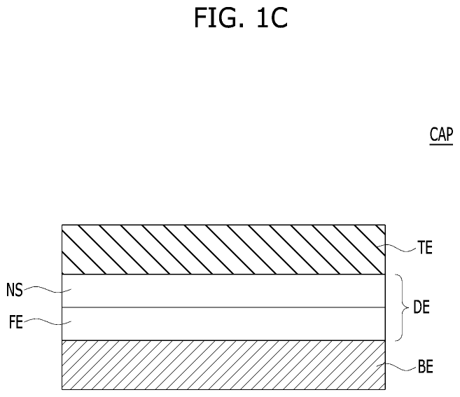

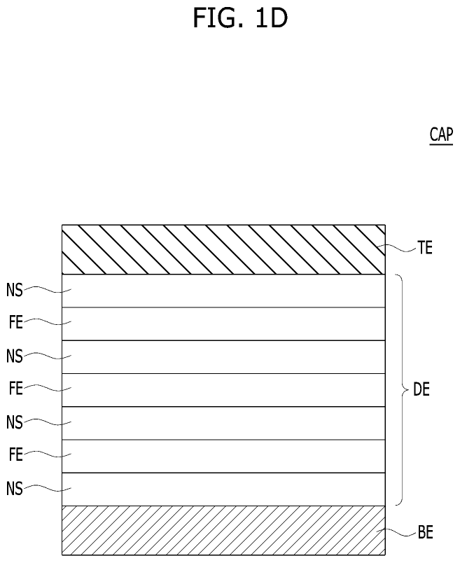

FIG. 1A is a cross-sectional view illustrating a capacitor in accordance with an embodiment of the present disclosure.

Referring to FIG. 1A, a capacitor CAP may include a bottom electrode BE, a top electrode TE, and a hybrid dielectric layer DE between the bottom electrode BE and the top electrode TE.

The bottom electrode BE and the top electrode TE may include a conductive material. The bottom electrode BE and the top electrode TE may each include a semiconductor material, a metal, a metal oxide, a metal nitride, or a combination thereof. For example, the bottom electrode BE and the top electrode TE may include polysilicon, silicon germanium, TiN, TaN, Pt, Au, Pd, Ni, Mo, W, WN, Ru, RuO, Nb doped SrTiO₃, SrRuO₃ or a combination thereof.

The hybrid dielectric layer DE may include at least one nanosheet material and at least one ferroelectric material. According to embodiments of the present disclosure, the hybrid dielectric layer DE may include a first nanosheet material NS1, a ferroelectric material FE, and a second nanosheet material NS2. The ferroelectric material FE may be disposed between the first and second nanosheet materials NS1 and NS2. Each of the first and second nanosheet materials NS1 and NS2 may include a paraelectric material. Each of the first and second nanosheet materials NS1 and NS2 may include a two-dimensional inorganic material. Each of the first and second nanosheet materials NS1 and NS2 may include a super high-k material including titanium (Ti), niobium (Nb), calcium (Ca), strontium (Sr), tantalum (Ta), europium (Eu), lanthanum (La) or a combination thereof. For example, each of the first and second nanosheet materials NS1 and NS2 may include Ti_{0.87}O₂, Ti_{0.91}O₂, Nb₃O₈, TiNbO₅, Ti₂NbO₇, Ti₅NbO₁₄, Ca₂Nb₃O₁₀, Ca₃Nb₄O₁₃, Ca₄Nb₅O₁₆, Sr₂Nb₃O₁₀, Sr₃Nb₄O₁₃, Sr₄Nb₅O₁₆, Ca₂Ta₃O₁₀, Ca₃Ta₄O₁₃, Ca₄Ta₅O₁₆, Sr₂Ta₃O₁₀, Sr₃Ta₄O₁₃, Sr₄Ta₅O₁₆, Eu_{0.53}Ta₂O₇, or LaNb₂O₇.

The ferroelectric material FE may include a perovskite-based material. For example, the ferroelectric material FE may include Hf₁₋ₓZrₓO₂ (0<x<1), doped Hf₁₋ₓZrₓO₂ (dopant: La, Si, Y, Al), Ba₁₋ₓSrₓTiO₃ (0<x<1), PbTiO₃, PbZr₁₋ₓTiₓO₃ (0<x<1), or BiFeO₃.

According to another embodiment of the present disclosure, in the hybrid dielectric layer DE, the second nanosheet material NS2 may be omitted. In other words, the hybrid dielectric layer DE may include a stack of the first nanosheet material NS1 and the ferroelectric material FE.

According to other embodiments of the present disclosure, in the hybrid dielectric layer DE, either the first nanosheet material NS2 or the second nanosheet material NS1 may be omitted.

FIGS. 1B to 1D are cross-sectional views illustrating capacitors in accordance with other embodiments of the present disclosure.

Referring to FIGS. 1B and 1C, a hybrid dielectric layer DE may have a bi-layer structure that includes a nanosheet material NS and a ferroelectric material FE. The nanosheet material NS may include a super high-k material containing titanium (Ti), niobium (Nb), calcium (Ca), strontium (Sr), tantalum (Ta), europium (Eu), lanthanum (La), or a combination thereof. For example, the nanosheet material NS may include Ti_{0.87}O₂, Ti_{0.91}O₂, Nb₃O₈, TiNbO₅, Ti₂NbO₇, Ti₅NbO₁₄, Ca₂Nb₃O₁₀, Ca₃Nb₄O₁₃, Ca₄Nb₅O₁₆, Sr₂Nb₃O₁₀, Sr₃Nb₄O₁₃, Sr₄Nb₅O₁₆, Ca₂Ta₃O₁₀, Ca₃Ta₄O₁₃, Ca₄Ta₅O₁₆, Sr₂Ta₃O₁₀, Sr₃Ta₄O₁₃, Sr₄Ta₅O₁₆, Eu_{0.53}Ta₂O₇, or LaNb₂O₇. The ferroelectric material FE may include a perovskite-based material. For example, the ferroelectric material FE may include Hf₁₋ₓZrₓO₂ (0<x<1), doped Hf₁₋ₓZrₓO₂ (dopant: La, Si, Y, Al), Ba₁₋ₓSrₓTiO₃ (0<x<1), PbTiO₃, PbZr₁₋ₓTiₓO₃ (0<x<1), or BiFeO₃.

In FIG. 1B, the nanosheet material NS may contact the bottom electrode BE, and the ferroelectric material FE, which is stacked on the nanosheet material NS, may contact the top electrode TE.

In FIG. 1C, the nanosheet material NS may be stacked on the ferroelectric material FE and may contact the top electrode TE, and the ferroelectric material FE may contact the bottom electrode BE.

Referring to FIG. 1D, a hybrid dielectric layer DE may have a laminated stack structure that includes a plurality of nanosheet materials NS and a plurality of ferroelectric materials FE. In the hybrid dielectric layer DE, the nanosheet materials NS and the ferroelectric materials FE may be alternately stacked in a laminate stack structure. The nanosheet material (NS) may include Ti_{0.87}O₂, Ti_{0.91}O₂, Nb₃O₈, TiNbO₅, Ti₂NbO₇, Ti₅NbO₁₄, Ca₂Nb₃O₁₀, Ca₃Nb₄O₁₃, Ca₄Nb₅O₁₆, Sr₂Nb₃O₁₀, Sr₃Nb₄O₁₃, Sr₄Nb₅O₁₆, Ca₂Ta₃O₁₀, Ca₃Ta₄O₁₃, Ca₄Ta₅O₁₆, Sr₂Ta₃O₁₀, Sr₃Ta₄O₁₃, Sr₄Ta₅O₁₆, Eu_{0.53}Ta₂O₇, or LaNb₂O₇. The ferroelectric material FE may include a perovskite-based material. For example, the ferroelectric material FE may include Hf₁₋ₓZrₓO₂ (0<x<1), doped Hf₁₋ₓZrₓO₂ (dopant: La, Si, Y, Al), Ba₁₋ₓSrₓTiO₃ (0<x<1), PbTiO₃, PbZr₁₋ₓTiₓO₃ (0<x<1), or BiFeO₃.

In FIG. 1D, in the laminated stack structure of the hybrid dielectric layer DE, the lowermost nanosheet material NS may contact the bottom electrode BE, and the uppermost nanosheet material NS may contact the top electrode TE.

Referring again to FIG. 1D, the negative capacitance of the capacitor may be further increased because the total interface between the nanosheet materials NS and the ferroelectric materials FE is increased by nature of the laminated stack structure of the hybrid dielectric layer DE.

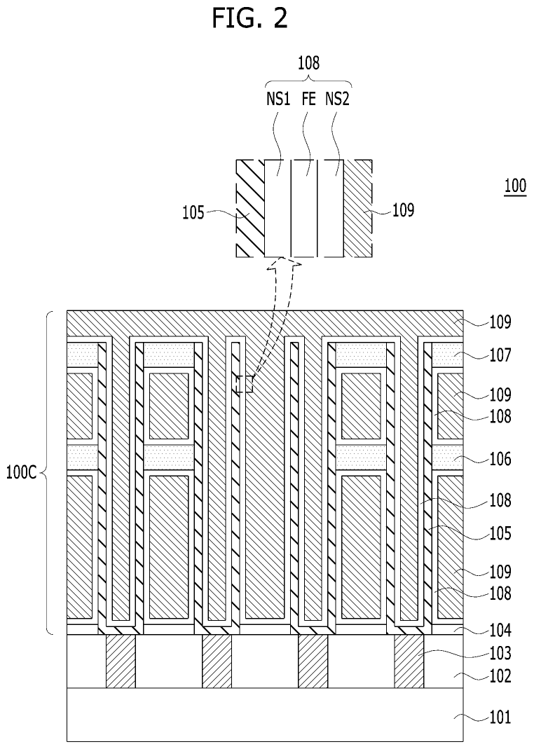

FIG. 2 illustrates a semiconductor device in accordance with an embodiment of the present disclosure.

Referring to FIG. 2, a semiconductor device 100 may include a substrate 101 and a capacitor structure 100C disposed over the substrate 101. The capacitor structure 100C may include a plurality of bottom electrodes 105, supporters 106 and 107 supporting the bottom electrodes 105, a hybrid dielectric layer 108 over the bottom electrodes 105 and the supporters 106 and 107, and a top electrode 109 over the hybrid dielectric layer 108. Each of the bottom electrodes 105 may be electrically connected to the substrate 101 through a contact plug 103. The contact plugs 103 may penetrate the inter-layer dielectric layer 102, which is located over the substrate 101, to be coupled to the substrate 101. The contact plugs 103 may be referred to as ‘storage node contact plugs’.

The substrate 101 may include a material appropriate for semiconductor processing. For example, the substrate 101 may include a semiconductor substrate, and the semiconductor substrate may be formed of a material containing silicon. The semiconductor substrate may include silicon, monocrystalline silicon, polysilicon, amorphous silicon, silicon germanium, monocrystalline silicon germanium, polycrystalline silicon germanium, carbon-doped silicon, combinations thereof, or multi-layers thereof. The semiconductor substrate may also include other semiconductor materials, such as germanium. The semiconductor substrate may include a III/V-group semiconductor substrate, for example, a compound semiconductor substrate, such as GaAs. The semiconductor substrate may include a Silicon-On-Insulator (SOI) substrate.

Bottom portions of the bottom electrodes 105 may penetrate an etch stop layer 104, which may be located on the inter-layer dielectric layer 102, to be coupled to the contact plugs 103. The bottom electrodes 105 may have a cylinder shape. The outer walls of the bottom electrodes 105 may be supported by the supporters 106 and 107. In FIG. 2, the supporters 106 and 107 may include a plate-like structure extending laterally to support the neighboring or adjacent bottom electrodes 105. The supporters 106 and 107 may include at least one or more supporters (not illustrated herein). In an example, a multi-level dielectric supporter may include an upper-level supporter 107 and a lower-level supporter 106. The upper-level supporter 107 may support the outer walls of the bottom electrodes 105 at or near the top of the bottom electrodes 105. The lower-level supporter 106 may be vertically spaced apart from the upper-level supporter 107 and positioned at a lower-level than the upper-level supporter 107. The lower-level supporter 106 may support the outer walls of the bottom electrodes 105 between the top of the bottom electrode 105 and the substrate 101 or etch stop layer 104. The upper-level supporter 107 may be thicker in the vertical direction than the lower-level supporter 106. The distance between the upper-level supporter 107 and the lower-level supporter 106 may be smaller than the distance between the lower-level supporter 106 and the etch stop layer 104. From the perspective of a top view, each of the upper-level supporter 107 and the lower-level supporter 106 may have a plate-like structure. The upper-level supporter 107 and the lower-level supporter 106 may include the same material or different materials. The upper-level supporter 107 and the lower-level supporter 106 may be formed of a nitride-based material. For example, the upper-level supporter 107 and the lower-level supporter 106 may be formed of silicon nitride, silicon carbon nitride, or silicon boron nitride. The bottom electrodes 105 may be in direct contact with the supporters 106 and 107, respectively.

The bottom electrodes 105 may have a cylinder shape. The bottom electrodes 105 may include a semiconductor material or a metal-based material. The metal-based material may include a metal, a metal nitride, a metal silicon nitride, a conductive metal oxide, a metal silicide, a noble metal, or a combination thereof. For example, the bottom electrodes 105 may include polysilicon, silicon germanium, TiN, TaN, Pt, Au, Pd, Ni, Mo, W, WN, Ru, RuO, Nb-doped SrTiO₃, SrRuO₃, or a combination thereof.

The hybrid dielectric layer 108 may be disposed between the bottom electrode 105 and the top electrode 109. The hybrid dielectric layer may include a high-k material having a higher dielectric constant than silicon oxide and silicon nitride. The hybrid dielectric layer 108 may include a first nanosheet material NS1, a ferroelectric material FE, and a second nanosheet material NS2. The ferroelectric material FE may be sandwiched between the first nanosheet material NS1 and the second nanosheet material NS2. Each of the first and second nanosheet materials NS1 and NS2 may include a paraelectric material. The first and second nanosheet materials NS1 and NS2 may each include a two-dimensional inorganic material. Each of the first and second nanosheet materials NS1 and NS2 may include a super high-k material including titanium (Ti), niobium (Nb), calcium (Ca), strontium (Sr), tantalum (Ta), europium (Eu), lanthanum (La) or a combination thereof. For example, the first and second nanosheet materials NS1 and NS2 may each include Ti_{0.87}O₂, Ti_{0.91}O₂, Nb₃O₈, TiNbO₅, Ti₂NbO₇, Ti₅NbO₁₄, Ca₂Nb₃O₁₀, Ca₃Nb₄O₁₃, Ca₄Nb₅O₁₆, Sr₂Nb₃O₁₀, Sr₃Nb₄O₁₃, Sr₄Nb₅O₁₆, Ca₂Ta₃O₁₀, Ca₃Ta₄O₁₃, Ca₄Ta₅O₁₆, Sr₂Ta₃O₁₀, Sr₃Ta₄O₁₃, Sr₄Ta₅O₁₆, Eu_{0.53}Ta₂O₇, or LaNb₂O₇. The ferroelectric material FE may include a perovskite-based material. For example, ferroelectric material FE may include Hf₁₋ₓZrₓO₂ (0<x<1), doped Hf₁₋ₓZrₓO₂ (dopant: La, Si, Y, Al), Ba₁₋ₓSrₓTiO₃ (0<x<1), PbTiO₃, PbZr₁₋ₓTiₓO₃ (0<x<1), or BiFeO₃.

The top electrode 109 may include a semiconductor material or a metal-based material. The metal-based material may include a metal, a metal nitride, a metal silicon nitride, a conductive metal oxide, a metal silicide, a noble metal, or a combination thereof. For example, the bottom electrodes 105 may include polysilicon, silicon germanium, TiN, TaN, Pt, Au, Pd, Ni, Mo, W, WN, Ru, RuO, Nb-doped SrTiO₃, SrRuO₃, or a combination thereof.

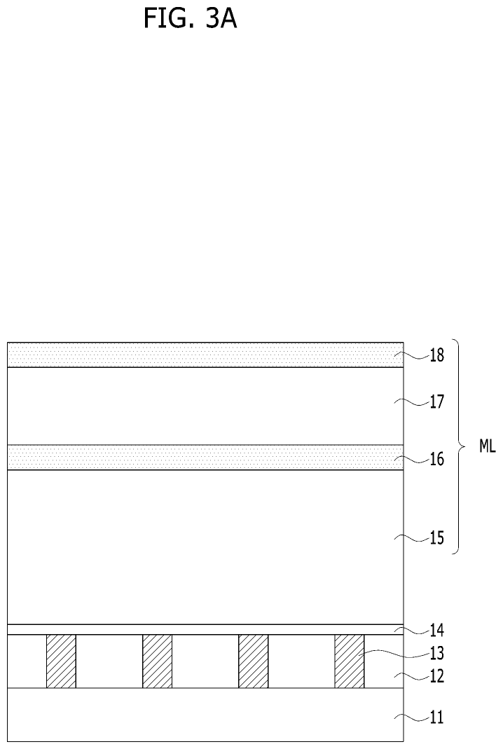

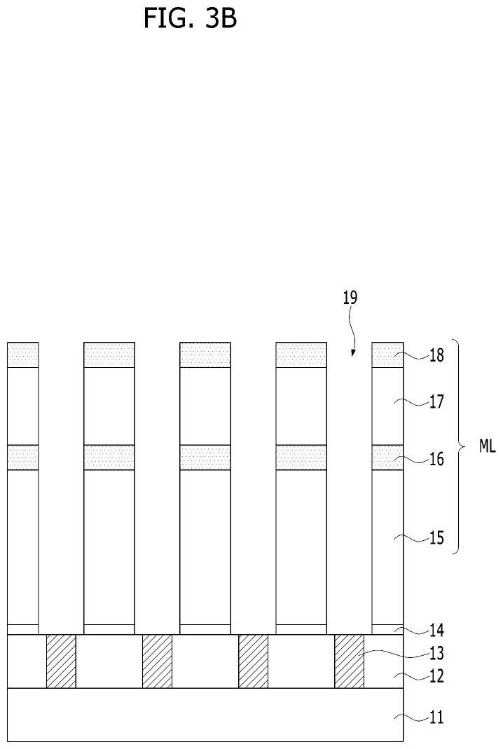

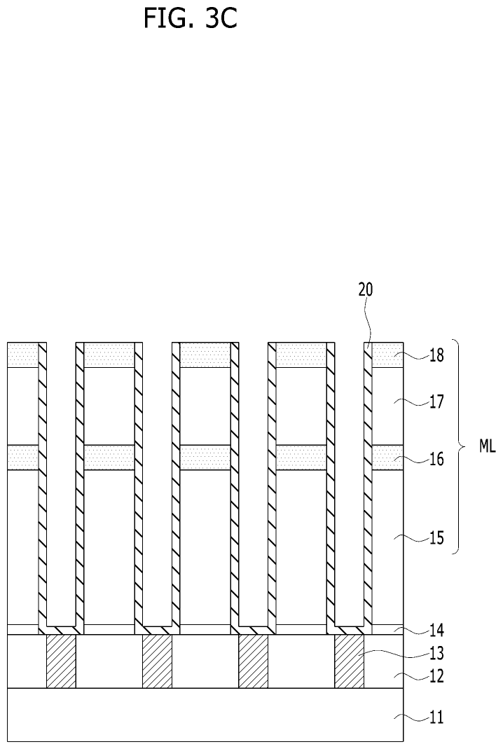

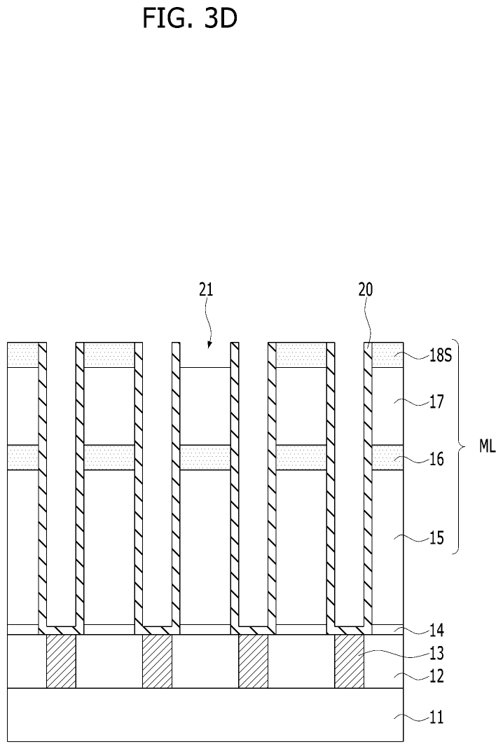

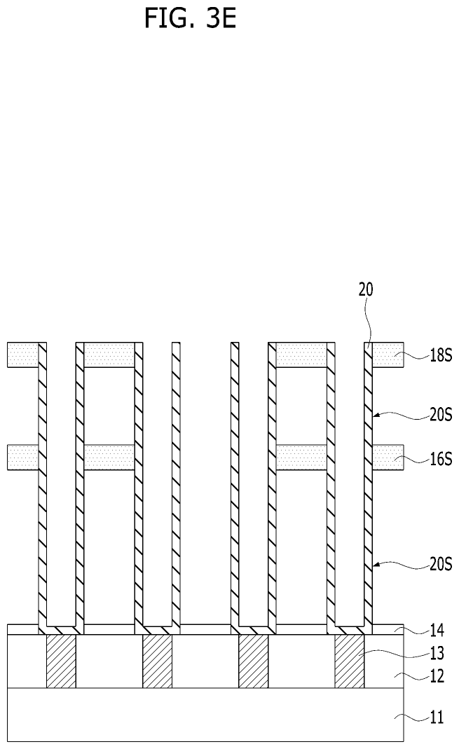

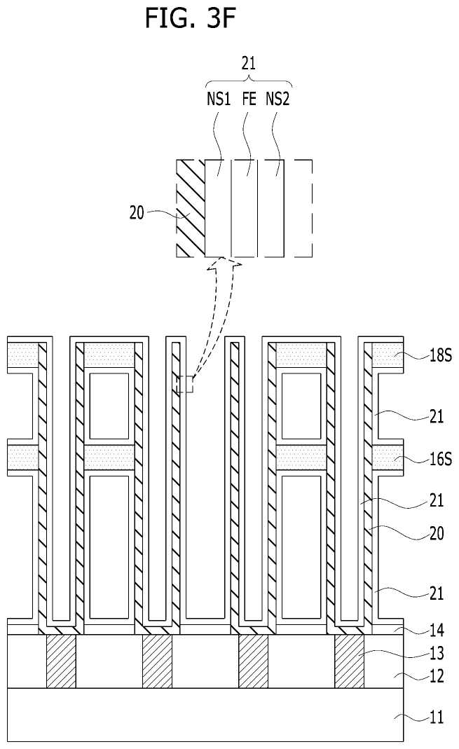

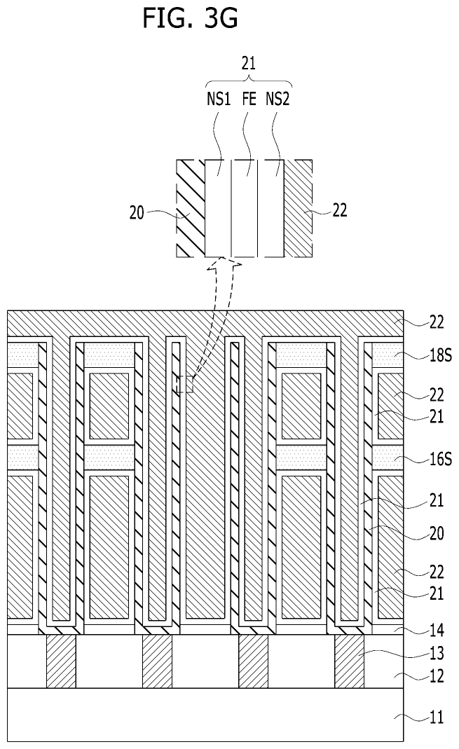

FIGS. 3A to 3G illustrate an example of a method for fabricating a semiconductor device in accordance with an embodiment of the present disclosure.

Referring to FIG. 3A, an inter-layer dielectric layer 12 may be formed over a substrate 11. The substrate 11 may be a semiconductor substrate, such as for example, a silicon (Si) substrate, a germanium (Ge) substrate, or a silicon-germanium (Si—Ge) substrate. The inter-layer dielectric layer 12 may include at least one among silicon oxide, silicon nitride, and silicon oxynitride.

Contact plugs 13 may be formed in the inter-layer dielectric layer 12. The contact plugs 13 may penetrate the inter-layer dielectric layer 12 to be electrically connected to a portion of the substrate 11. The contact plugs 13 may include a semiconductor material, such as a metal, a metal nitride, a metal silicide, or a combination thereof. For example, the contact plugs 13 may include polysilicon, tungsten, tungsten nitride, titanium nitride, titanium silicon nitride, titanium silicide, cobalt silicide, or a combination thereof. According to another embodiment of the present disclosure, the contact plugs 13 may be stacked in the order of a semiconductor material, a metal silicide, a metal nitride, and a metal. The contact plugs 13 may be spaced apart from each other in a lateral direction.

Although not illustrated, a plurality of word lines and bit lines may be formed over the substrate 11, in the substrate 11, or both. The inter-layer dielectric layer 12 may be formed to cover the word lines and the bit lines. Impurity regions (not shown) may be formed in the substrate 11 on both sides of each of the word lines, and each of the contact plugs 13 may be coupled to one from among the impurity regions.

An etch stop layer 14 may be formed over the inter-layer dielectric layer 12 and the contact plugs 13, and a mold structure ML may be formed over the etch stop layer 14. The etch stop layer 14 may include silicon nitride. The mold structure ML may be a stack structure including different dielectric materials. For example, the mold structure ML may be stacked on the etch stop layer 14 in the order of a first mold layer 15, a first support layer 16, a second mold layer 17, and a second support layer 18. The first support layer 16 and the second support layer 18 may include a material having an etch selectivity with respect to the first and second mold layers 15 and 17. The first support layer 16 and the second support layer 18 may include a silicon nitride-based material. For example, when the first mold layer 15 and the second mold layer 17 includes silicon oxide, and the first support layer 16 and the second support layer 18 may include silicon nitride. According to other embodiments of the present disclosure, the first support layer 16 and the second support layer 18 may include silicon carbon nitride or silicon boron nitride. According to further embodiments of the present disclosure, each of the first support layer 16 and the second support layer 18 may include a stack of silicon nitride and silicon carbon nitride or a stack of silicon nitride and silicon boron nitride.

Referring to FIG. 3B, a plurality of openings 19 may be formed in the mold structure ML. The openings 19 may be formed by etching the mold structure ML using a mask layer (not shown). To form the openings 19, the second support layer 18, the second mold layer 17, the first support layer 16, and the first mold layer 15 may be sequentially etched. The etching process used to form the openings 19 may stop at the etch stop layer 14. To form the openings 19, a dry etching process, a wet etching process, or a combination thereof may be used. The openings 19 may be referred to as holes in which a bottom electrode (or a storage node) is to be formed.

Subsequently, the etch stop layer 14 may be etched to expose the upper surface of each of the contact plugs 13 below the openings 19.

The openings 19 may be formed by a double patterning process. For example, the mask layer for forming the openings 19 may have a mesh-shape which is formed by combining a spacer patterning technique that is performed twice.

Referring to FIG. 3C, a bottom electrode 20 may be formed in each of the openings 19. The bottom electrode 20 may fill the inside or sidewalls of the openings 19. The bottom electrode 20 may have a cylinder-shape. To form the bottom electrode 20, a conductive material may be conformally deposited over the openings 19 and then the conductive material may be etched back. The bottom electrode 20 may include polysilicon or a metal-based material. The metal-based material may include a metal, a metal nitride, a metal silicon nitride, a conductive metal oxide, a metal silicide, a noble metal, or a combination thereof. For example, the bottom electrode 20 may include polysilicon, silicon germanium, TiN, TaN, Pt, Au, Pd, Ni, Mo, W, WN, Ru, RuO, Nb-doped SrTiO₃, SrRuO₃, or a combination thereof.

Referring to FIG. 3D, a portion of the second support layer 18 may be etched to form an upper-level supporter opening 21. Remaining upper-level supporters 18S may be plate-shaped. Upper-level supporters 18S may contact upper outer walls of the bottom electrodes 20 common to openings 19. Some surfaces of the second mold layer 17 may be exposed by the upper-level supporter 18S. The upper-level supporter 18S may have a shape that partially or completely surrounds the outer walls of the bottom electrodes 20. The upper-level supporter 18S may prevent the bottom electrodes 20 from collapsing in the subsequent process of removing the second mold layer 17.

From the perspective of a top view, the upper-level supporter opening 21 may have a shape that partially exposes the outer walls of the three neighboring bottom electrodes 20. According to another embodiment of the present disclosure, the upper-level supporter opening 21 may have a shape that partially exposes the outer walls of at least four or more bottom electrodes 20. The cross section of the upper-level supporter opening 21 may have a triangular, quadrangular, parallelogram, pentagonal, hexagonal or honeycomb shape.

By the upper-level supporter opening 21, the outer walls of all the bottom electrodes 20 may be partially exposed. This may be referred to as an ‘all open bottom electrode array’.

According to another embodiment of the present disclosure, the upper outer wall of the at least one bottom electrode 20 may not be exposed due to the upper-level supporter opening 21. For example, among the bottom electrodes 20, there may be at least one bottom electrode 20 that is not exposed by the upper-level supporter opening 21 but fully covered by the upper-level supporter 18S. This may be referred to as a ‘1-span bottom electrode array’.

Referring to FIG. 3E, the second mold layer 17 below the upper-level supporter opening 21 may be removed. The second mold layer 17 may be removed by a wet dip-out process. The second mold layer 17 may be selectively removed, and thus the surface of the first support layer 16 may be exposed. The wet dip-out process for removing the second mold layer 17 may be performed using an etching solution capable of selectively removing the second mold layer 17. When the second mold layer 17 includes silicon oxide, the second mold layer 17 may be removed by a wet etching process using hydrofluoric acid (HF), for example.

After the second mold layer 17 is removed, the first support layer 16 under opening 21 may be removed, and the remaining portions of first support layer 16 may be etched to form the lower-level supporter 16S. The lower-level supporter 16S may contact the outer walls of the bottom electrodes 20. Some surfaces of the first mold layer 15 may be exposed by the lower-level supporter 16S. The lower-level supporter 16S may have a shape that partially surrounds the outer walls of the bottom electrodes 20. The lower-level supporter 16S may prevent the bottom electrodes 20 from collapsing in the subsequent process of removing the first mold layer 15. The lower-level supporter 16S and the upper-level supporter 18S may have the substantially the same cross-sectional shape.

Subsequently, the first mold layer 15 may be removed. The first mold layer 15 may be removed by a wet dip-out process. The first mold layer 15 may be selectively removed, and thus the surface of the etch stop layer 14 may be exposed. The wet dip-out process for removing the first mold layer 15 may be performed using an etching solution capable of selectively removing the first mold layer 15. When the first mold layer 15 includes silicon oxide, the first mold layer 15 may be removed by a wet etching process using hydrofluoric acid (HF).

A lower-level supporter 16S and an upper-level supporter 18S supporting the outer walls of the bottom electrodes 20 may be formed by a series of processes as described above with reference to FIGS. 3B to 3E. The outer walls 20S of the bottom electrodes 20 may be partially exposed between the lower-level supporter 16S and the upper-level supporter 18S. Also, the outer walls 20S of the bottom electrodes 20 may be partially exposed between the lower-level supporter 16S and the etch stop layer 14.

Referring to FIG. 3F, a hybrid dielectric layer 21 may be formed over the bottom electrodes 20, the upper-level supporter 18S and the lower-level supporter 16S.

The hybrid dielectric layer 21 may include a first nanosheet material NS1, a ferroelectric material FE, and a second nanosheet material NS2. The first and second nanosheet materials NS1 and NS2 may each include a paraelectric material. Each of the first and second nanosheet materials NS1 and NS2 may include a two-dimensional inorganic material. The first and second nanosheet materials NS1 and NS2 may each include a super high-k material including titanium (Ti), niobium (Nb), calcium (Ca), strontium (Sr), tantalum (Ta), europium (Eu), lanthanum (La) or a combination thereof. For example, the first and second nanosheet materials NS1 and NS2 may include Ti_{0.87}O₂, Ti_{0.91}O₂, Nb₃O₈, TiNbO₅, Ti₂NbO₇, Ti₅NbO₁₄, Ca₂Nb₃O₁₀, Ca₃Nb₄O₁₃, Ca₄Nb₅O₁₆, Sr₂Nb₃O₁₀, Sr₃Nb₄O₁₃, Sr₄Nb₅O₁₆, Ca₂Ta₃O₁₀, Ca₃Ta₄O₁₃, Ca₄Ta₅O₁₆, Sr₂Ta₃O₁₀, Sr₃Ta₄O₁₃, Sr₄Ta₅O₁₆, Eu_{0.53}Ta₂O₇, or LaNb₂O₇.

The ferroelectric material FE may include a perovskite-based material. For example, the ferroelectric material FE may include Hf₁₋ₓZrₓO₂ (0<x<1), doped Hf₁₋ₓZrₓO₂ (dopant: La, Si, Y, Al), Ba₁₋ₓSrₓTiO₃ (0<x<1), PbTiO₃, PbZr₁₋ₓTiₓO₃ (0<x<1), or BiFeO₃.

The hybrid dielectric layer 21 may have a double-layer structure as illustrated in FIGS. 1B and 1C. The hybrid dielectric layer 21 may also have a laminated stack structure as illustrated in FIG. 1D.

Referring to FIG. 3G, a top electrode 22 may be formed over the hybrid dielectric layer 21. The top electrode 22 may include a semiconductor material or a metal-based material. The metal-based material may include a metal, a metal nitride, a metal silicon nitride, a conductive metal oxide, a metal silicide, a noble metal, or a combination thereof. For example, the top electrode 22 may include polysilicon, silicon germanium, TiN, TaN, Pt, Au, Pd, Ni, Mo, W, WN, Ru, RuO, Nb-doped SrTiO₃, SrRuO₃, or a combination thereof.

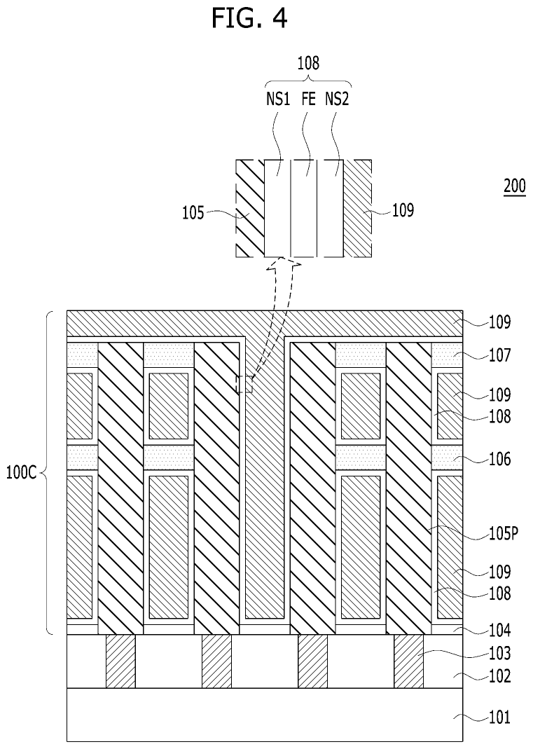

FIG. 4 illustrates a semiconductor device in accordance with another embodiment of the present disclosure. A semiconductor device 200 of FIG. 4 may be substantially similar to the semiconductor device 100 shown in FIG. 2. Therefore, detailed descriptions on the constituent elements that are the same in both in FIG. 2 and FIG. 4 may be omitted.

Referring to FIG. 4, the semiconductor device 200 may include a capacitor structure 100C. The capacitor structure 100C may include a plurality of bottom electrodes 105P, supporters 106 and 107 supporting the bottom electrodes 105P, a hybrid dielectric layer 108 over the bottom electrodes 105P and the supporters 106 and 107, and a top electrode 109 over the hybrid dielectric layer 108. Each of the bottom electrodes 105P of the capacitor structure 100C may be electrically connected to the substrate 101 through a contact plug 103. The contact plugs 103 may penetrate the inter-layer dielectric layer 102, which is located over the substrate 101, to be coupled to the substrate 101. The contact plugs 103 may be referred to as storage node contact plugs. The bottom electrodes 105P may have a pillar shape.

The hybrid dielectric layer 108 of FIG. 4 may include a high-k material having a higher dielectric constant than silicon oxide and silicon nitride. The hybrid dielectric layer 108 may include a first nanosheet material NS1, a ferroelectric material FE, and a second nanosheet material NS2. The first and second nanosheet materials NS1 and NS2 may include a paraelectric material. The first and second nanosheet materials NS1 and NS2 may include a two-dimensional inorganic material. The first and second nanosheet materials NS1 and NS2 may include a super high-k material including titanium (Ti), niobium (Nb), calcium (Ca), strontium (Sr), tantalum (Ta), europium (Eu), lanthanum (La) or a combination thereof. For example, the first and second nanosheet materials NS1 and NS2 may include Ti_{0.87}O₂, Ti_{0.91}O₂, Nb₃O₈, TiNbO₅, Ti₂NbO₇, Ti₅NbO₁₄, Ca₂Nb₃O₁₀, Ca₃Nb₄O₁₃, Ca₄Nb₅O₁₆, Sr₂Nb₃O₁₀, Sr₃Nb₄O₁₃, Sr₄Nb₅O₁₆, Ca₂Ta₃O₁₀, Ca₃Ta₄O₁₃, Ca₄Ta₅O₁₆, Sr₂Ta₃O₁₀, Sr₃Ta₄O₁₃, Sr₄Ta₅O₁₆, Eu_{0.53}Ta₂O₇, or LaNb₂O₇. The ferroelectric material FE may include a perovskite-based material. For example, the ferroelectric material FE may include Hf₁₋ₓZrₓO₂ (0<x<1), doped Hf₁₋ₓZrₓO₂ (dopant: La, Si, Y, Al), Ba₁₋ₓSrₓTiO₃ (0<x<1), PbTiO₃, PbZr₁₋ₓTiₓO₃ (0<x<1), or BiFeO₃. The hybrid dielectric layer 108 may have a double layer structure as illustrated in FIGS. 1B and 1C. The hybrid dielectric layer 108 may also have a laminated stack structure as illustrated in FIG. 1D.

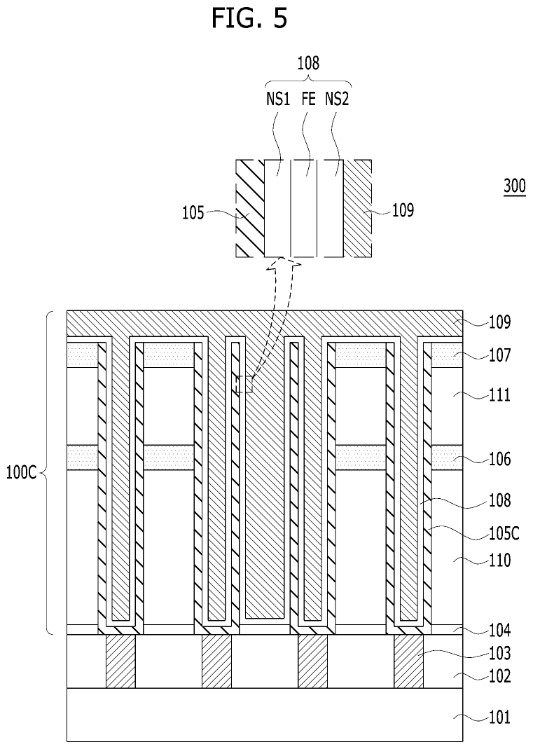

FIG. 5 illustrates a semiconductor device in accordance with another embodiment of the present disclosure. A semiconductor device 300 of FIG. 5 may be substantially similar to the semiconductor device 100 shown in FIG. 2. Therefore, detailed descriptions on the constituent elements that are the same in both in FIG. 2 and FIG. 5 may be omitted.

Referring to FIG. 5, the semiconductor device 300 may include a capacitor structure 100C. The capacitor structure 100C may include a plurality of bottom electrodes 105C, supporters 106 and 107 supporting the bottom electrodes 105C, a hybrid dielectric layer 108 over the bottom electrodes 105C and the supporters 106 and 107, and a top electrode 109 over the hybrid dielectric layer 108. Each of the bottom electrodes 105C of the capacitor structure 100C may be electrically connected to the substrate 101 through a contact plug 103. The contact plugs 103 may penetrate the inter-layer dielectric layer 102, which is located over the substrate 101, to be coupled to the substrate 101. The contact plugs 103 may be referred to as storage node contact plugs. The bottom electrodes 105P may have a tubular shape with a closed lower end.

The hybrid dielectric layer 108 of FIG. 5 may include a high-k material having a higher dielectric constant than silicon oxide and silicon nitride. The hybrid dielectric layer 108 may include a first nanosheet material NS1, a ferroelectric material FE, and a second nanosheet material NS2. The first and second nanosheet materials NS1 and NS2 may include a paraelectric material. The first and second nanosheet materials NS1 and NS2 may include a two-dimensional inorganic material. The first and second nanosheet materials NS1 and NS2 may include a super high-k material including titanium (Ti), niobium (Nb), calcium (Ca), strontium (Sr), tantalum (Ta), europium (Eu), lanthanum (La) or a combination thereof. For example, the first and second nanosheet materials NS1 and NS2 may include Ti_{0.87}O₂, Ti_{0.91}O₂, Nb₃O₈, TiNbO₅, Ti₂NbO₇, Ti₅NbO₁₄, Ca₂Nb₃O₁₀, Ca₃Nb₄O₁₃, Ca₄Nb₅O₁₆, Sr₂Nb₃O₁₀, Sr₃Nb₄O₁₃, Sr₄Nb₅O₁₆, Ca₂Ta₃O₁₀, Ca₃Ta₄O₁₃, Ca₄Ta₅O₁₆, Sr₂Ta₃O₁₀, Sr₃Ta₄O₁₃, Sr₄Ta₅O₁₆, Eu_{0.53}Ta₂O₇, or LaNb₂O₇. The ferroelectric material FE may include a perovskite-based material. For example, the ferroelectric material FE may include Hf₁₋ₓZrₓO₂ (0<x<1), doped Hf₁₋ₓZrₓO₂ (dopant: La, Si, Y, Al), Ba₁₋ₓSrₓTiO₃ (0<x<1), PbTiO₃, PbZr₁₋ₓTiₓO₃ (0<x<1), or BiFeO₃. The hybrid dielectric layer 108 may have a double layer structure as illustrated in FIGS. 1B and 1C. The hybrid dielectric layer 108 may also have a laminated stack structure as illustrated in FIG. 1D.

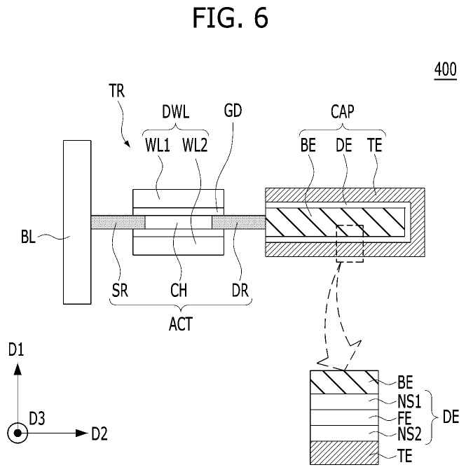

FIG. 6 illustrates a semiconductor device in accordance with another embodiment of the present disclosure. A semiconductor device 400 of FIG. 6 shows a structure of a three-dimensional (3D) Dynamic Random Access Memory (DRAM) cell.

Referring to FIG. 6, the semiconductor device 400 may include a bit line BL, a transistor TR, and a capacitor CAP. The transistor TR may include an active layer ACT, gate dielectric layers GD, and a double word line DWL. The capacitor CAP may include a storage node BE, a dielectric layer DE, and a plate node TE (not illustrated). The bit line BL may have a pillar shape extending in a first direction D1. The active layer ACT may have a bar shape extending in a second direction D2, which intersects with the first direction D1. The double word line DWL may have a line shape extending in a third direction D3, which intersects with the first and second directions D1 and D2.

The bit line BL may be vertically oriented in the first direction D1. The bit line BL may be referred to as a vertically oriented bit line or a pillar-type bit line. The bit line BL may include a conductive material. The bit line BL may include a silicon-based material, a metal-based material, or a combination thereof. The bit line BL may include polysilicon, a metal, a metal nitride, a metal silicide, or a combination thereof. The bit line BL may include polysilicon, titanium nitride, tungsten, or a combination thereof. For example, the bit line BL may include polysilicon or titanium nitride (TiN) which is doped with an N-type impurity. The bit line BL may include a stack (TiN/W) of titanium nitride and tungsten.

The double word line DWL may extend in the third direction D3, and the active layer ACT may extend in the second direction D2. The active layer ACT may be arranged laterally from the bit line BL. The double word line DWL may include a first word line WL1 and a second word line WL2. The first word line WL1 and the second word line WL2 may be spaced apart in the first direction D1 with the active layer ACT interposed therebetween. A gate dielectric layer GD may be formed over the upper and lower surfaces of the active layer ACT.

The active layer ACT may include a semiconductor material. For example, the active layer ACT may include silicon, germanium, or silicon-germanium. The active layer ACT may include a channel CH, a first source/drain region SR between the channel CH and the bit line BL, and a second source/drain region DR between the channel CH and the capacitor CAP. According to another embodiment of the present disclosure, the active layer ACT may include an oxide semiconductor material. For example, the oxide semiconductor material may include Indium Gallium Zinc Oxide (IGZO). When the active layer ACT is formed of an oxide semiconductor material, the channel CH may be formed of an oxide semiconductor material, and the first and second source/drain regions SR and DR may be omitted. According to another embodiment of the present disclosure, the active layer ACT may include monocrystalline silicon, and thus the mobility of a transistor may be improved.

The first source/drain region SR and the second source/drain region DR may be doped with an impurity of the same conductivity type. For example, the first source/drain region SR and the second source/drain region DR may be doped with an N-type impurity or a P-type impurity. The first source/drain region SR and the second source/drain region DR may include at least one impurity selected among arsenic (As), phosphorus (P), boron (B), indium (In), and combinations thereof. A first side of the first source/drain region SR may be in contact with the bit line BL, and a second side of the first source/drain region SR may be in contact with the channel CH. A first side of the second source/drain region DR may be in contact with the storage node BE, and a second side of the second source/drain region DR may be in contact with the channel CH. The second side of the first source/drain region SR and the second side of the second source/drain region DR may partially overlap with the first and second word lines WL1 and WL2, respectively. The lateral length of the channel CH in the second direction D2 may be smaller than the lateral length of the first and second source/drain regions SR and DR in the second direction D2. According to another embodiment of the present disclosure, the lateral length of the channel CH in the second direction D2 may be greater than the lateral length of the first and second source/drain regions SR and DR in the second direction D2.

The transistor TR is a cell transistor and may have a double word line DWL. In the double word line DWL, a first word line WL1 and a second word line WL2 may have the same potential. The same word line driving voltage may be applied to the first word line WL1 and the second word line WL2. As such, the semiconductor device 400 in accordance with an embodiment of the present disclosure may have a double word line DWL in which two first and second word lines WL1 and WL2 are disposed adjacent to one channel CH.

The active layer ACT may have a thickness that is less than the thicknesses of the first and second word lines WL1 and WL2. In other words, a vertical thickness of the active layer ACT in the first direction D1 may be smaller than a vertical thickness of each of the first and second word lines WL1 and WL2 in the first direction D1.

As described above, a thin active layer ACT may be referred to as a thin-body active layer. The thin active layer ACT may include a thin channel CH. Hereinafter, the channel CH may be simply referred to as a ‘thin-body channel (CH)’.

The upper and lower surfaces of the active layer ACT may have a flat or substantial flat surface. In other words, the upper and lower surfaces of the active layer ACT may be parallel to each other in the second direction D2.

The gate dielectric layer GD may include silicon oxide, silicon nitride, a metal oxide, a metal oxynitride, a metal silicate, a high-k material, a ferroelectric material, an anti-ferroelectric material, or a combination thereof. The gate dielectric layer GD may include SiO₂, Si₃N₄, HfO₂, Al₂O₃, ZrO₂, AlON, HfON, HfSiO, HfSiON, or a combination thereof.

The first and second word lines WL1 and WL2 of the double word line DWL may include a metal, a metal mixture, a metal alloy, or a semiconductor material. The double word line DWL may include titanium nitride, tungsten, polysilicon, or a combination thereof. For example, the double word line DWL may include a TiN/W stack in which titanium nitride and tungsten are sequentially stacked. The double word line DWL may include an N-type work function material or a P-type work function material. The N-type work function material may have a low work function, which is lower than approximately 4.5 eV, and the P-type work function material may have a high work function, which is higher than approximately 4.5 eV.

According to an embodiment of the present disclosure, the double word line DWL may include a pair of two word lines, which include the first word line WL1 and the second word line WL2, with the active layer ACT interposed therebetween.

The capacitor CAP may be disposed laterally in the second direction D2 from the transistor TR. The capacitor CAP may include a storage node BE, which extends laterally from the active layer ACT in the second direction D2. The capacitor CAP may further include a hybrid dielectric layer DE and a plate node TE over the storage node BE. The storage node BE, the hybrid dielectric layer DE, and the plate node TE may be arranged laterally in the second direction D2. The storage node BE may have a laterally oriented pillar shape. The hybrid dielectric layer DE may conformally cover the outer wall of the storage node BE. The storage node BE may be electrically connected to the second source/drain region DR.

The storage node BE may have a three-dimensional (3D) structure, and the storage node BE having a three-dimensional structure may have a horizontal three-dimensional structure which is oriented in the second direction D2. As an example of the 3D structure, the storage node BE may have a pillar shape that extends in the second direction D2. According to another embodiment of the present disclosure, the storage node BE may have a cylindrical shape or a plate shape.

The hybrid dielectric layer DE may include a high-k material having a higher dielectric constant than silicon oxide and silicon nitride. The hybrid dielectric layer DE may include a first nanosheet material NS1, a ferroelectric material FE, and a second nanosheet material NS2. The first and second nanosheet materials NS1 and NS2 may include a paraelectric material. The first and second nanosheet materials NS1 and NS2 may include a 2D inorganic material. The first and second nanosheet materials NS1 and NS2 may include a super high-k material including titanium (Ti), niobium (Nb), calcium (Ca), strontium (Sr), tantalum (Ta), europium (Eu), lanthanum (La) or a combination thereof. For example, the first and second nanosheet materials NS1 and NS2 may include Ti_{0.87}O₂, Ti_{0.91}O₂, Nb₃O₈, TiNbO₅, Ti₂NbO₇, Ti₅NbO₁₄, Ca₂Nb₃O₁₀, Ca₃Nb₄O₁₃, Ca₄Nb₅O₁₆, Sr₂Nb₃O₁₀, Sr₃Nb₄O₁₃, Sr₄Nb₅O₁₆, Ca₂Ta₃O₁₀, Ca₃Ta₄O₁₃, Ca₄Ta₅O₁₆, Sr₂Ta₃O₁₀, Sr₃Ta₄O₁₃, Sr₄Ta₅O₁₆, Eu_{0.53}Ta₂O₇, or LaNb₂O₇. The ferroelectric material FE may include a perovskite-based material. For example, the ferroelectric material FE may include Hf₁₋ₓZrₓO₂ (0<x<1), doped Hf₁₋ₓZrₓO₂ (dopant: La, Si, Y, Al), Ba₁₋ₓSrₓTiO₃ (0<x<1), PbTiO₃, PbZr₁₋ₓTiₓO₃ (0<x<1), or BiFeO₃. The hybrid dielectric layer DE may have a double layer structure as illustrated in FIGS. 1B and 1C. The hybrid dielectric layer DE may be a laminated stack structure as illustrated in FIG. 1D.

Referring to FIG. 6, improvement of an on-current Ion and stabilization of a threshold voltage Vth may be simultaneously secured by using the hybrid dielectric layer DE and the double word line DWL.

Also, when an oxide semiconductor material is used as the thin body channel CH, on-current may be secured sufficiently due to low leakage characteristics. Thus, even if a plate capacitor with a small area is formed, the cell density of 3D DRAM may be increased.

Also, manufacturing process restrictions may be reduced because the capacitor forming process can be performed at a room temperature so to reduce deleterious effects on 3D DRAM cells.

According to an embodiment of the present disclosure, a capacitor having a high dielectric constant of approximately 200 or more may be formed by utilizing a hybrid dielectric layer including a nanosheet material.

According to an embodiment of the present disclosure, a capacitor having a negative capacitance may be formed by using a hybrid dielectric layer including a nanosheet material.

The desirable effects to be obtained in the embodiments of the present disclosure are not limited to those effects mentioned above. Other effects not mentioned above may also be clearly understood by those of ordinary skill in the art to which the present invention pertains from the description in the disclosure.

While the present invention has been described with respect to the specific embodiments, it will be apparent to those skilled in the art that various changes and modifications may be made without departing from the spirit and scope of the invention as defined in the following claims.

What is claimed is:

1. A capacitor, comprising:
a bottom electrode;
a top electrode; and
a hybrid dielectric layer including at least one nanosheet material disposed between the bottom electrode and the top electrode.

2. The capacitor of claim 1, wherein the hybrid dielectric layer has a negative capacitance.

3. The capacitor of claim 1, wherein the hybrid dielectric layer includes:
a first nanosheet material;
a second nanosheet material; and
a ferroelectric material between the first nanosheet material and the second nanosheet material.

4. The capacitor of claim 3, wherein the first nanosheet material and the second nanosheet material each include Ti_{0.87}O₂, Ti_{0.91}O₂, Nb₃O₈, TiNbO₅, Ti₂NbO₇, Ti₅NbO₁₄, Ca₂Nb₃O₁₀, Ca₃Nb₄O₁₃, Ca₄Nb₅O₁₆, Sr₂Nb₃O₁₀, Sr₃Nb₄O₁₃, Sr₄Nb₅O₁₆, Ca₂Ta₃O₁₀, Ca₃Ta₄O₁₃, Ca₄Ta₅O₁₆, Sr₂Ta₃O₁₀, Sr₃Ta₄O₁₃, Sr₄Ta₅O₁₆, Eu_{0.53}Ta₂O₇, or LaNb₂O₇.

5. The capacitor of claim 3, wherein the ferroelectric material includes a perovskite-based material.

6. The capacitor of claim 3, wherein the ferroelectric material includes Hf₁₋ₓZrₓO₂ (0<x<1), doped Hf₁₋ₓZrₓO₂ (dopant: La, Si, Y, Al), Ba₁₋ₓSrₓTiO₃ (0<x<1), PbTiO₃, PbZr₁₋ₓTiₓO₃ (0<x<1), or BiFeO₃.

7. The capacitor of claim 1, wherein the hybrid dielectric layer includes a double layer structure including one nanosheet material and one ferroelectric material, or a laminated stack structure in which a plurality of nanosheet materials and a plurality of ferroelectric materials are alternately stacked.

8. The capacitor of claim 1, wherein the nanosheet material has a thickness of approximately 0.4 to 2 nm and has a dielectric constant that is greater than approximately 200.

9. The capacitor of claim 1, wherein the nanosheet material includes a crystalline material.

10. A semiconductor device, comprising:
a transistor including a first source/drain region, a second source/drain region, and a channel between the first source/drain region and a second source/drain region;
a word line positioned over the channel of the transistor;
a bit line coupled to the first source/drain region of the transistor; and
a capacitor coupled to the second source/drain region of the transistor,
wherein the capacitor includes:
a bottom electrode coupled to the second source/drain region;
a top electrode; and
a hybrid dielectric layer including at least one nanosheet material disposed between the bottom electrode and the top electrode.

11. The semiconductor device of claim 10, wherein the hybrid dielectric layer has a negative capacitance.

12. The semiconductor device of claim 10, wherein the hybrid dielectric layer includes:
a first nanosheet material;
a second nanosheet material; and
a ferroelectric material between the first nanosheet material and the second nanosheet material.

13. The semiconductor device of claim 12, wherein the first nanosheet material and the second nanosheet material each include Ti_{0.87}O₂, Ti_{0.91}O₂, Nb₃O₈, TiNbO₅, Ti₂NbO₇, Ti₅NbO₁₄, Ca₂Nb₃O₁₀, Ca₃Nb₄O₁₃, Ca₄Nb₅O₁₆, Sr₂Nb₃O₁₀, Sr₃Nb₄O₁₃, Sr₄Nb₅O₁₆, Ca₂Ta₃O₁₀, Ca₃Ta₄O₁₃, Ca₄Ta₅O₁₆, Sr₂Ta₃O₁₀, Sr₃Ta₄O₁₃, Sr₄Ta₅O₁₆, Eu_{0.53}Ta₂O₇, or LaNb₂O₇.

14. The semiconductor device of claim 12, wherein the ferroelectric material includes a perovskite-based material.

15. The semiconductor device of claim 12, wherein the ferroelectric material includes Hf₁₋ₓZrₓO₂ (0<x<1), doped Hf₁₋ₓZrₓO₂ (dopant: La, Si, Y, Al), Ba₁₋ₓSrₓTiO₃ (0<x<1), PbTiO₃, PbZr₁₋ₓTiₓO₃ (0<x<1), or BiFeO₃.

16. The semiconductor device of claim 10, wherein the hybrid dielectric layer includes a double layer structure including one nanosheet material and one ferroelectric material, or a laminated stack structure in which a plurality of nanosheet materials and a plurality of ferroelectric materials are alternately stacked.

17. The semiconductor device of claim 10, wherein the nanosheet material has a thickness of approximately 0.4 to 2 nm and has a dielectric constant that is greater than approximately 200.

18. The semiconductor device of claim 10, wherein the nanosheet material includes a crystalline material.

19. The semiconductor device of claim 10, wherein the word line includes a buried word line.

20. The semiconductor device of claim 10, wherein the bit line extends vertically in a first direction, and
the first source/drain region, the channel, and the second source/drain region are arranged laterally between the bit line and the capacitor in a second direction, and
the word line is laterally oriented in a third direction intersecting with the bit line.
